(19) United States
(12) Patent Application Publication
(10) Pub. No.: US 2026/0063692 A1
(43) Pub. Date: Mar. 5, 2026

(54) METHOD, ASSEMBLY AND SENSE UNIT FOR MEASURING THE FREQUENCY RESPONSE OF A PLURALITY OF ELECTRICAL OBJECTS

(71) Applicant: MEGGER SWEDEN AB, Danderyd (SE)

(72) Inventor: Simon CARLSSON, Farsta (SE)

(21) Appl. No.: 19/101,083

(22) PCT Filed: Jun. 29, 2023
(86) PCT No.: PCT/SE2023/050673

§ 371 Date: Feb. 4, 2025

(30) Foreign Application Priority Data
Jul. 6, 2022 (SE) 2250849-3

(51) Int. Cl. G01R 23/02; G01R 31/62

(52) U.S. Cl. CPC G01R 23/02; G01R 31/62

(57) ABSTRACT

A method of measuring the frequency response of a plurality of electrical objects to be measured comprises connecting a first mechanical connecting device of a plurality of mechanical connecting devices to a first electrical object to be measured, connecting a second mechanical connecting device to a second electrical object to be measured, and connecting a third mechanical connecting device to a third electrical object to be measured. The mechanical connecting devices are then connected to a testing unit. By remotely and electrically disconnecting selected mechanical connecting devices from the testing unit at a distance from the testing unit and measuring the frequency response of the electrical objects to be measured for which the mechanical connecting device is not electrically disconnected, disturbances in the measurement results from test objects different from the ones currently tested are avoided. A sense unit and an assembly for measuring the frequency response of a plurality of electrical objects are also provided.

### TECHNICAL FIELD

The present invention relates generally to measuring electrical characteristics, preferably the frequency response, of a plurality of electrical objects, such as high-voltage objects, to be measured and more specifically a method, an assembly and a sense unit in which the connection and disconnection of the electrical objects are made remotely.

### BACKGROUND ART

Frequency Response Analysis (FRA) is a method to electrically characterize an electrical asset with windings, such as a transformer, reactor, rotating machine etc., by applying an AC voltage of varying frequency or an electrical impulse at one terminal and at the same time monitoring the resulting voltage at another terminal. Typically, this is done between terminals connected to the same winding, A to B, B to C etc., and the result is plotted in a curve with magnitude, preferably measured in dB, on the Y-axis and frequency on the X-axis. As an electrical asset, such as a transformer, is a very complex circuit of resistances, inductances, and capacitances (RLC), each asset will have a unique appearance of this curve, which can be seen as a “fingerprint”. Ideally, the electrical properties of an asset should be constant from manufacturing and through its entire service life. However, events such as transportation, high fault currents, overhaul or even earthquakes may change the internals of the asset, typically windings, core, tank, connections, bushings etc., so that it no longer performs as intended.

In such cases, FRA is an important method that allows the tester to detect any changes in the electrical setup of the asset by comparing a reference curve, typically recorded in manufacturing or during commissioning, with a curve recorded after the suspected adverse event. By interpreting the difference between the curves, it can be determined if there is a change to the asset and also in which component or subsystem that is affected.

FRA measurements are made to de-energized assets and only one phase at a time is connected and tested as all connected external components will affect the fingerprint curve of the asset with their RLC contribution. It is thus required to only connect one phase (two test leads) at a time and to reconnect the test leads multiple times. The connection points may be very hard to reach and in general all reconnections consume time, increase the risk of incorrect connection or grounding and add significant safety hazard to the operator.

### SUMMARY OF INVENTION

An object of the present invention is to mitigate the problems of prior art and to provide a method, an assembly, and a sense unit wherein multiple test objects can be measured in a safe and efficient way.

According to a first aspect of the invention, there is provided a method of measuring the frequency response of a plurality of electrical objects to be measured, the method comprising the following steps: connecting a first mechanical connecting device of a plurality of mechanical connecting devices to a first electrical object to be measured, connecting a second mechanical connecting device of the plurality of mechanical connecting devices to a second electrical object to be measured, connecting a third mechanical connecting device of the plurality of mechanical connecting devices to a third electrical object to be measured, connecting the plurality of mechanical connecting devices to a testing unit, the method being characterized by the steps of remotely and electrically disconnecting selected mechanical connecting devices from the testing unit, wherein the location of the disconnection is at a distance from the testing unit, and measuring the frequency response of the electrical objects to be measured for which the mechanical connecting device is not electrically disconnected.

In a preferred embodiment, the step of measuring the frequency response of one of the plurality of electrical objects to be measured for which the mechanical connecting device is not disconnected comprises measuring at least one phase of a three-phase electrical device.

In a preferred embodiment, the step of remotely disconnecting selected mechanical connecting devices from the respective cables comprises opening a mechanical relay.

In a preferred embodiment, automated switching between phases is provided without physical reconnection of leads.

In a preferred embodiment, the step of remotely and electrically disconnecting selected mechanical connecting devices from the testing unit comprises opening a mechanical relay by applying a DC voltage on a cable connecting the mechanical connecting device to the testing device.

According to a second aspect of the invention, there is provided a sense unit for measuring the frequency response of an electrical object to be measured, the sense unit comprising a mechanical connecting device, and an interconnection device adapted to connect and disconnect the mechanical connecting device to/from a testing device, the sense unit being characterized in that the interconnection device is at a distance from the testing device, and the interconnection device is remotely controllable to electrically connect and disconnect the mechanical connecting device and the testing device.

In a preferred embodiment, the mechanical connecting device is a clamp.

In a preferred embodiment, the interconnecting device comprises a mechanical relay.

In a preferred embodiment, the mechanical relay is adapted to be operated by applying a DC voltage on a cable connecting the sense unit to the testing device.

In a preferred embodiment, the mechanical connecting device and the interconnection device are integrated into one single unit.

In a preferred embodiment, the sense unit comprises a testing unit connected to the interconnection device, the testing unit preferably comprising a wireless communication unit.

In a preferred embodiment, diodes are integrated in the sense unit to discriminate between the lower test voltage and the higher disconnection voltage.

According to a third aspect of the invention, there is provided an assembly for measuring the frequency response of a plurality of electrical objects (40a-c) to be measured, the assembly comprising: a testing unit, a plurality of sense assemblies, each sense assembly comprising a connection device to the testing unit, the assembly being characterized in that each sense assembly further comprises a sense unit according to any one of claims.

In a preferred embodiment, the testing unit is any of the following: a frequency response analyser, a sweep frequency response analyser, and a direct frequency response analyser.

In a preferred embodiment, the connection devices are cables, preferably two-wire cables, more preferably coaxial cables.

In a preferred embodiment, a switch box is provided between the test unit (10) and the sense assemblies.

The invention allows sense units to be connected to all terminals of a device to be tested at the same time and to be left connected during the measuring, even if that particular connection is not used in that instant. In this way, the measurement, such as an FRA measurement, is not affected by other connections not used at the time.

### BRIEF DESCRIPTION OF DRAWINGS

The invention is now described, by way of example, with reference to the accompanying drawings, in which:

FIG. 1 is an overall view of an assembly for measuring the frequency response of a plurality of electrical objects, comprising a testing unit, a switchbox, and sense units,

FIG. 2 shows in detail the design of the testing unit and the switchbox of the assembly shown in FIG. 1.

FIG. 3 is a detailed diagram of an embodiment of a sense unit of the assembly in FIG. 1,

FIG. 4 shows an example of the design of a sense unit,

FIG. 5 is a flow chart of a method of measuring the frequency response of a plurality of electrical objects.

FIG. 6 shows an overview of an alternative embodiment of an assembly for measuring the frequency response of a plurality of electrical objects.

### DESCRIPTION OF EMBODIMENTS

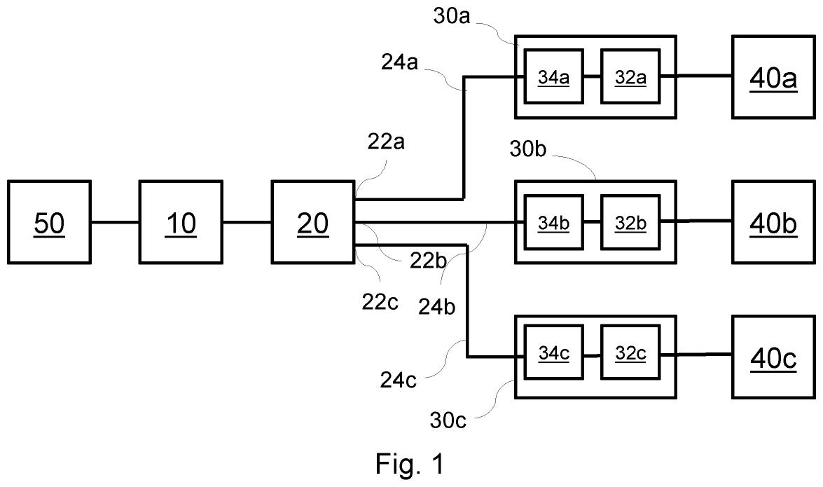

In the following, a detailed description of an assembly for measuring electrical characteristics, preferably the frequency response, of a plurality of electrical objects will be given, initially with reference to FIG. 1, which is an overall block diagram of the assembly.

In FIG. 1, the assembly, generally designated 1, comprises a testing unit 10 adapted for testing an electrical asset 40, such as a transformer. The electrical asset 40 comprises a plurality of electrical objects 40a-40c to be tested. In the case of a transformer, these electrical objects may be the windings of the different phases of the transformer. Thus, in the case of a three-phase transformer, the number of electrical objects is three. The testing unit 10 can operate according to different principles and can be for example a frequency response analyzer, a sweep frequency response analyzer, or a direct frequency response analyzer.

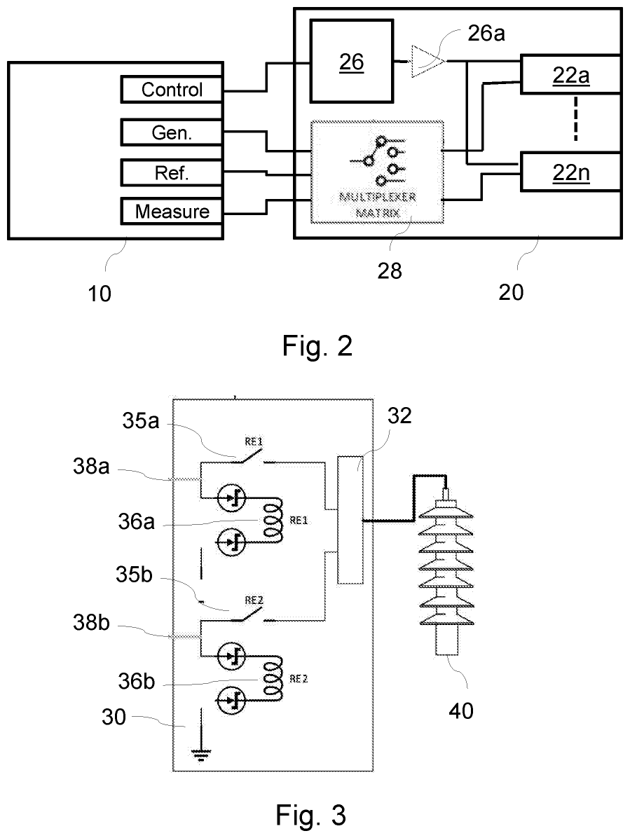

The testing unit 10 is connected to the plurality of test objects 40a-40c via a switchbox 20. The switchbox 20 comprises a plurality of ports 22a-20c provided to connect the switchbox 20 to the test objects via a respective sense unit 30a-30c. The interconnection between the testing unit 10 and the switchbox 20 will be described in more detail with reference to FIG. 2.

The sense units 30a-30c, preferably comprising clamps, are mechanically connected to a respective test object 40a-40c. With this mechanical connection, they are also electrically connected to the test objects. They are also connected to the switchbox 20. In the embodiment shown in FIG. 1, this connection is effected by means of electrical cables, 24a-24c, preferably coaxial cables, each interconnecting a port 22a-22c of the switchbox 20 and a respective sense unit 30a-30c. Alternatively, these interconnections may be wireless interconnections.

The testing unit 10 is optionally connected to a computer 50. In this computer the results of the measurements may be stored and analyzed.

Turning now to FIG. 2, the operation of the testing unit 10 and the switchbox 20 will be explained. The testing unit 10, by means of which the results of the measurements on the test objects are analyzed, operates with a number of signals, in the shown embodiment a control signal, a generator signal, a reference signal, and a measure signal. The control signal controls a processor 26 provided in the switchbox 20 to output control signals to the ports 22a-22c via an amplifier 26a. The processor 26 also controls a multiplexer matrix 28 adapted to interconnect the testing unit 10 to the different ports 22a-22c so that the generator and reference signals are provided to selected mechanical connecting devices and measure signals are received accordingly.

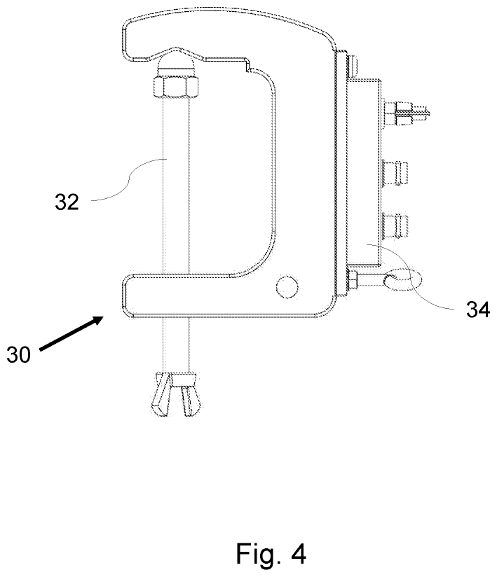

Turning now to FIGS. 3 and 4, the design of a sense unit 30 will be described. The sense unit 30 essentially comprises two parts integrated in the unit: a mechanical connecting device 32 and an interconnection device 34 adapted to connect and disconnect the mechanical connecting device to/from the switchbox 20. The mechanical connecting device 32 is preferably in the form of a clamp, see also FIG. 4, which is adapted to mechanically secure the sense unit 30 to the object 40 to be tested.

The interconnection device 34 comprises mechanical relays 35a, 35b adapted to be operated by means of a respective coil 36a, 36b. By applying appropriate input signals to a respective input 38a, 38b of the sense unit 30, the interconnection device 34 is remotely controllable to electrically connect and disconnect the mechanical connecting device 34 and the cable 24 interconnecting the switchbox 20 and the sense unit 30. In the context of this application, the term “remotely” should be interpreted as not within reach of an operator, i.e. that the location of the disconnection is at a distance from the testing unit 10. This may mean that the distance from an operator and/or the testing unit is at least two meters and even more preferably at least four meters. In a common situation this means that the sense units 30 are provided high above ground where the operator performing a test of a transformer or the like cannot manually connect and disconnect the sense units. Thus, to remove the problems associated with the switchbox being connected to an object not to be tested right now, the object is disconnected remotely.

Since the mechanical connecting device 32 and the interconnection device 34 are provided in the same sense unit 30, the lengths of the wires connected to a disconnected object 40a 40c is negligible. This in turn means that a disconnected object 40a-40c will not affect the measuring results of other objects 40 which are connected to the switchbox 20 and in turn the testing unit 10.

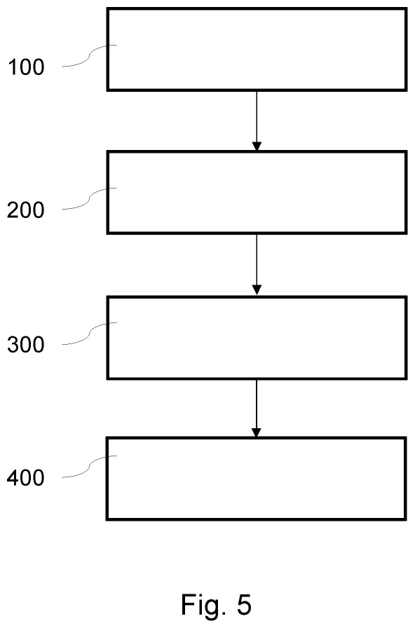

A method of measuring the frequency response of a plurality of electrical objects to be measured will now be described with reference to FIG. 5. First, in step 100, a plurality and at least three mechanical connecting devices 34 are mechanically and electrically connected to respective electrical object 40a-40c to be measured. In the example of a three-phase transformer, a first sense unit 30a is connected to the first phase of the transformer by means of the clamp 34 provided in the first sense unit 30a, a second sense unit 30b is connected to the second phase of the transformer and a third sense unit 30c is connected to the third phase of the transformer. Then, in step 200, the plurality of mechanical connecting devices 32 is connected to the testing unit 10 via the switchbox 20 and the cables 24. The assembly 1 for of measuring the frequency response of a plurality of electrical objects to be measured is thereby set up.

The testing unit 10 is then in step 300 remotely and electrically disconnected from selected mechanical connecting devices 32 by means of applying appropriate signals to the interconnection devices 34 in the different sense units 30. As explained above, this means that at least one object 40 to be tested is disconnected without affecting the measuring of the other objects to be tested and that the location of disconnection is at a distance from the testing unit 10. Thus, the frequency response of the electrical objects 40 for which the mechanical connecting device is not electrically disconnected are measured. Again, referring to the example of a three-phase transformer, the method may involve the following steps:
disconnecting the first phase and measuring between the second and third phases,
disconnecting the second phase and measuring between the first and third phases, and
disconnecting the third phase and measuring between the first and second phases.

Finally, in step 400 the frequency response of the electrical objects (40a, 40b, 40c) to be measured for which the mechanical connecting device is not electrically disconnected are measured.

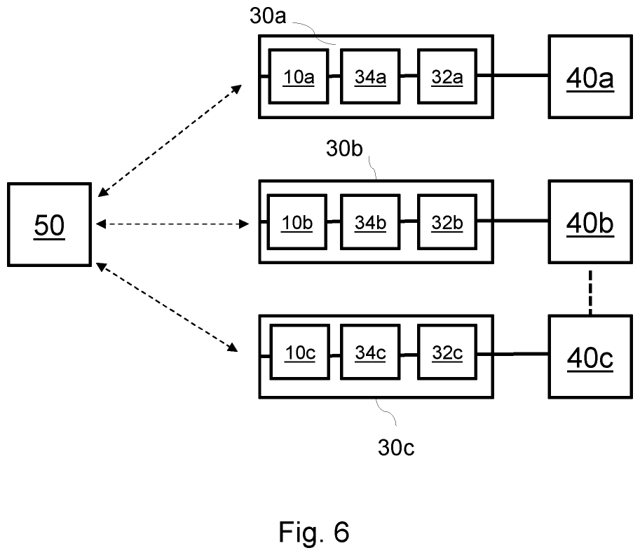

In FIG. 6, an alternative embodiment of an assembly for of measuring the frequency response of a plurality of electrical objects to be measured is shown. Instead of connecting a plurality of sense units 30 to a testing unit by means of a respective cable, each sense unit 30 comprises a respective testing unit 10a-c adapted for testing an electrical asset 40. In this case, no switchbox is required. Instead, each sense unit 30a-c comprises a wireless communication unit for wireless communication with a computer 50 in which the results of the measurements may be stored and analyzed.

In all other aspects, the assembly operates like the one described above with reference to FIG. 1. The sense units 30a-c are mechanically connected to a respective test object 40a-c by means of a respective mechanical connecting device 32a-c. With this mechanical connection, they are also electrically connected to the test objects. Each sense unit also comprises an interconnection device 34a-c adapted to remotely and electrically disconnecting the mechanical connecting devices 32a-c from the respective testing unit 10a-c.

It should be appreciated that the term “electrical object” should be interpreted broadly and can be one phase of a three-phase transformer, for example.

A method of measuring the frequency response of a plurality of electrical objects to be measured and an assembly and a sense unit for carrying out the method have been described. It will be appreciated that these can depart from the described embodiments as long as they fall within the scope of the appended claims. For example, the testing unit and the switchbox have been described as different units but it will be appreciated that these can be integrated into a single unit.

The sense units have been described as being connected to the switchbox by means of cables. It will be appreciated that the interconnection also may be wireless.

An example with measuring a three-phase transformer with three test objects, i.e., three test points, has been described. It will be appreciated that any asset with more than three test points falls within the scope of the present invention. Thus, measuring a three-phase transformer at four test points on the high voltage side and four test points on the low voltage side is another application of the present invention. Although the description of prefer embodiments relates to the frequency response, it will be appreciated that the described method, unit and assembly can be used more generally to measuring electrical characteristics.

1. A method of measuring the frequency response of a plurality of electrical objects to be measured, the method comprising the following steps:
connecting a first mechanical connecting device of a plurality of mechanical connecting devices to a first electrical object to be measured,
connecting a second mechanical connecting device of the plurality of mechanical connecting devices to a second electrical object to be measured,
connecting a third mechanical connecting device of the plurality of mechanical connecting devices to a third electrical object to be measured,
connecting the plurality of mechanical connecting devices to a testing unit, wherein the steps of
remotely and electrically disconnecting selected mechanical connecting devices from the testing unit, wherein the location of the disconnection is at a distance from the testing unit, and
measuring the frequency response of the electrical objects to be measured for which the mechanical connecting device is not electrically disconnected.

2. The method according to claim 1, wherein the step of measuring frequency response of one of the plurality of electrical objects to be measured for which the mechanical connecting device is not disconnected comprises measuring at least one phase of a three-phase electrical device.

3. The method according to claim 1, wherein the step of remotely disconnecting selected mechanical connecting devices comprises opening a mechanical relay.

4. The method according to claim 1, wherein automated switching between phases is provided without physical reconnection of leads.

5. The method according to claim 1, wherein the step of remotely and electrically disconnecting selected mechanical connecting devices from the testing unit comprises opening a mechanical relay by applying a DC voltage on a cable connecting the mechanical connecting device to the testing device.

6. A sense unit for measuring frequency response of an electrical object to be measured, the sense unit comprising:
a mechanical connecting device, and
an interconnection device adapted to connect and disconnect the mechanical connecting device to/from a testing device, wherein,
the interconnection device is at a distance from the testing device, and
the interconnection device is remotely controllable to electrically connect and disconnect the mechanical connecting device and the testing device.

7. The sense unit according to claim 6, wherein the mechanical connecting device is a clamp.

8. The sense unit according to claim 6, wherein the interconnecting device comprises a mechanical relay.

9. The sense unit according to claim 8, wherein the mechanical relay is adapted to be operated by applying a DC voltage on a cable connecting the sense unit to the testing device.

10. The sense unit according to claim 6, wherein the mechanical connecting device and the interconnection device are integrated into one single unit.

11. The sense unit according to claim 6, comprising a testing unit connected to the interconnection device, the testing unit preferably comprising a wireless communication unit.

12. The sense unit according to claim 6, comprising diodes integrated in the sense unit to discriminate between the lower test voltage and the higher disconnection voltage.

13. An assembly for measuring frequency response of a plurality of electrical objects to be measured, the assembly comprising:
a testing unit,
a plurality of sense assemblies, each sense assembly comprising
a connection device to the testing unit, wherein
each sense assembly further comprises a sense unit according to claim 6.

14. The assembly according to claim 13, wherein the testing unit is any of the following: a frequency response analyser, a sweep frequency response analyser, and a direct frequency response analyser.

15. The assembly according to claim 13, wherein the connection devices are cables, preferably two-wire cables, more preferably coaxial cables.

16. The assembly according to claim 13, comprising a switch box provided between the test unit and the sense assemblies.
